(19) United States
(12) Patent Application Publication
(10) Pub. No.: US 2020/0133047 A1
(43) Pub. Date: Apr. 30, 2020

(54) DISPLAY MODULE

(71) Applicant: SHARP KABUSHIKI KAISHA, Sakai City, Osaka (JP)

(72) Inventor: HIROAKI ISOBE, Sakai City, Osaka (JP)

(21) Appl. No.: 16/624,893

(22) PCT Filed: Jun. 15, 2018
(86) PCT No.: PCT/JP2018/022841

§ 371 Date: Dec. 19, 2019

(30) Foreign Application Priority Data
Jun. 22, 2017 (JP) 2017-122614

(51) Int. Cl. G02F 1/1345; H05K 1/02; H05K 1/18; H05K 1/14

(52) U.S. Cl. CPC G02F 1/13452; H05K 1/0215; H05K 1/189; H05K 2201/10136; H05K 1/0259; H05K 2201/056; H05K 1/147

(57) ABSTRACT

A display module ESD resistance of which is improved is achieved. In a display module (1) that includes: a display panel (10); a flexible printed circuit board (20) that is connected to the display panel (10); and a circuit board (30) that supplies a drive signal to the display panel (10) via the flexible printed circuit board (20), the flexible printed circuit board (20) includes an exposed portion (28), in which a conductive portion (24) connected to a ground is exposed, on a rear surface side of a connection surface (27) to the display panel (10).

### TECHNICAL FIELD

The present invention relates to a display module.

### BACKGROUND ART

Conventionally, there has been a display module in which a flexible printed circuit board is attached to a display panel. In such a display module, in order to prevent occurrence of ESD (Electrostatic Discharge) failure, a ground region in which a conductive layer is formed and a wiring region in which a wiring pattern is formed are formed in the same layer and at least a part of a terminal region is covered with a shielding portion that includes the ground region (for example, refer to PTL 1).

### CITATION LIST

### Patent Literature

PTL 1: Japanese Unexamined Patent Application Publication No. 2009-186777 (published on Aug. 20, 2009)

### SUMMARY OF INVENTION

### Technical Problem

It has been desired that ESD resistance of a display module such as a COG (Chip on Glass) model in which a semiconductor integrated circuit is directly mounted on a glass substrate of a display panel or an in-panel driver model in which a driver is included in a display panel be further improved.

The invention has been made in view of the aforementioned circumstances, and aims to achieve a display module ESD resistance of which is improved.

### Solution to Problem

In order to solve the aforementioned problem, a display module according to the invention has a configuration in which, in a display module including: a display panel; a flexible printed circuit board that is connected to the display panel; and a circuit board that supplies a drive signal to the display panel via the flexible printed circuit board, the flexible printed circuit board includes an exposed portion, in which a conductive portion connected to a ground is exposed, on a rear surface side of a connection surface to the display panel.

### Advantageous Effects of Invention

According to an aspect of the invention, it is possible to improve ESD resistance of a display module.

### BRIEF DESCRIPTION OF DRAWINGS

FIG. 1 is an enlarged view of a part of a display module according to Embodiment 1 of the invention.

FIG. 2 is a sectional view illustrating a configuration of a flexible printed circuit board.

FIG. 3 is a plan view illustrating a connection configuration of a display panel, the flexible printed circuit board, and a circuit board.

FIG. 4 is a sectional view illustrating a connection configuration of the circuit board and a case ground.

FIG. 5 is a view illustrating a configuration of a flexible printed circuit board according to Embodiment 2 of the invention.

FIG. 6 is a view illustrating a configuration of a flexible printed circuit board according to Embodiment 3 of the invention.

### DESCRIPTION OF EMBODIMENTS

### Embodiment 1

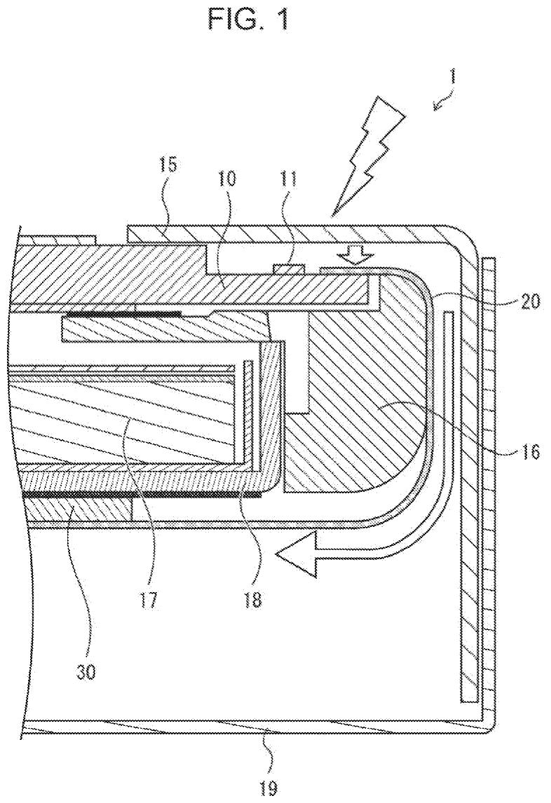

Hereinafter, Embodiment 1 of the invention will be described in detail with reference to FIGS. 1 to 3.

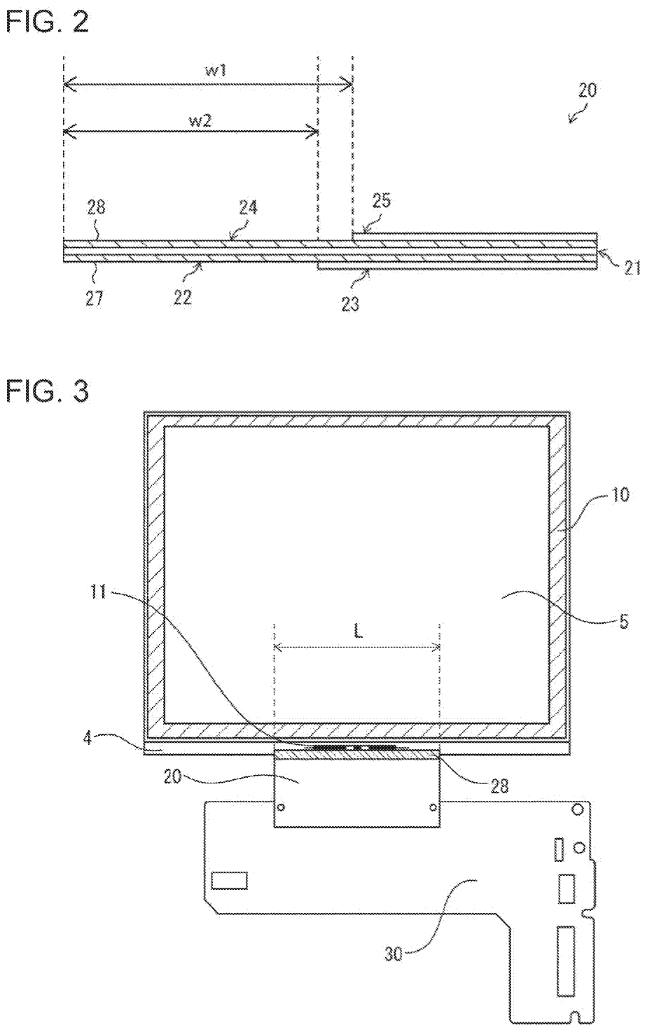

FIG. 1 is an enlarged view of a part of a display module 1 according to Embodiment 1. FIG. 2 is a view illustrating a configuration of a flexible printed circuit board 20. FIG. 3 illustrates a display panel 10, the flexible printed circuit board 20 connected thereto, and a circuit board 30.

As illustrated in FIG. 1, the display module 1 includes the display panel 10, a backlight 17, and the circuit board 30. Moreover, the display module 1 includes the flexible printed circuit board 20 that is connected to the display panel 10 and the circuit board 30 and supplies a drive signal from the circuit board 30 to the display panel 10. In addition, the display module 1 includes a backlight case 18 that supports the backlight 17.

Furthermore, the display module 1 includes a plastic frame 16 which supports the display panel 10, the backlight 17, the circuit board 30, the flexible printed circuit board 20, and the backlight case 18, a bezel 15, and a rear cover 19. A configuration in which the backlight case 18, the bezel 15, and the rear cover 19 are formed of, for example, metal is able to be provided.

The display panel 10 is a liquid crystal display panel in which liquid crystal is held between two glass substrates. A COG (Chip on Glass) 11 is directly mounted on a glass substrate of the display panel 10. A configuration in which the COG 11 is connected to the glass substrate with use of an anisotropic conductive film (ACF) is able to be provided.

Although illustration is omitted, the display panel 10 may be a liquid crystal display panel of an in-panel driver model, in which a driver circuit by which the display panel 10 is driven is directly mounted on the glass substrate.

As illustrated in FIG. 2, the flexible printed circuit board 20 includes a base member 21, a conductor layer 22, and a conductive portion 24. The base member 21 is formed of a material that is excellent in a heat-resisting property and an insulation property. As the material of the base member 21, polyimide resin is able to be suitably used. The conductor layer 22 and the conductive portion 24 are respectively formed on a front surface of the base member 21 and a rear surface of the base member 21 so as to hold the base member 21 therebetween.

The conductor layer 22 and the conductive portion 24 are respectively formed by bonding a conductor, which is made of gold plating or copper, to the front and rear surfaces of the base member 21. Outer surfaces of the conductor layer 22 and the conductive portion 24 are respectively covered with film coverlays (cover layers) 23 and 25 that are formed of a material that is excellent in a heat-resisting property and an insulation property. As the material of the film coverlays 23 and 25, polyimide resin is able to be suitably used.

In the conductor layer 22 that is provided on a side of the front surface of the base member 21, a connection surface 27 that is not covered with the film coverlay 23 is provided. The connection surface 27 of the flexible printed circuit board 20 is connected to a terminal region 4 (refer to FIG. 3) of the display panel 10 with use of an anisotropic conductive film (ACF). The display panel 10 and the flexible printed circuit board 20 are connected by performing press-bonding, by which a load and heat are applied, in a state where the anisotropic conductive film is held between the terminal region 4 of the display panel 10 and the connection surface 27.

In the conductive portion 24 that is provided on a side of the rear surface of the base member 21, an exposed portion 28 which is not covered with the film coverlay 25 and in which the conductor is exposed is provided. The exposed portion 28 is provided so as to be positioned on a rear surface side of the connection surface 27.

As illustrated in FIG. 3, the terminal region 4 of the display panel 10 is provided in an edge side of the display panel 10, which is in an outside of a display region of the display panel 10. Although illustration is omitted, in the terminal region 4, a plurality of wires and a plurality of terminals provided in the plurality of wires are formed.

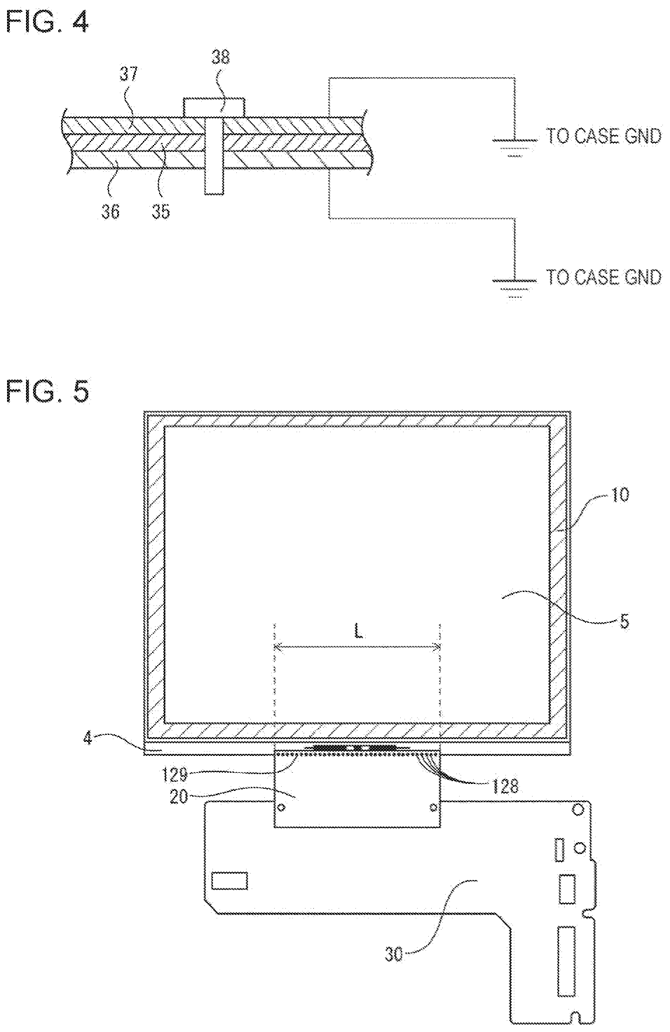

The exposed portion 28 of the flexible printed circuit board 20 is electrically connected to the circuit board 30. The circuit board 30 is connected to a case-side ground through connection to a power source connector. Moreover, as illustrated in FIG. 4, a configuration in which the circuit board 30 has a ground exposed pattern 35 in which a part of a wire is exposed may be provided. Then, a configuration in which, to at least one of a backlight metal case 36, a circuit board cover 37, and the like, each of which is connected to the ground of the case and made of metal, the ground exposed pattern 35 is screwed together by a screw 38 or connected by conductive tape or the like may be provided. Thereby, the exposed portion 28 of the flexible printed circuit board 20 is connected to the ground via the circuit board 30.

Note that, when a configuration in which an electronic component is mounted on the flexible printed circuit board 20 or the COG 11 is caused to have a function of driving the display panel is provided, the circuit board 30 is omitted in some cases. In such a display module 1 that does not include the circuit board 30, it is possible to provide a configuration in which the flexible printed circuit board 20 is connected at least one of a ground of the display panel 10, the ground of the case, and a ground of a power source.

According to such configurations, as illustrated in FIG. 1, it is possible to cause ESD (electrostatic discharge), which is generated outside the display module 1, to flow to the conductive portion 24 of the flexible printed circuit board 20 from the exposed portion 28 and to be discharged from the ground via the flexible printed circuit board 20. In this manner, electrostatic discharge is caused to flow a bypass via the flexible printed circuit board 20 and to be discharged. Thus, it is possible to prevent electrostatic discharge from affecting driving of the display panel by flowing into the COG 11, a panel driver in the display panel 10, or the like, and ESD failure from occurring in an electronic component.

Moreover, by providing the flexible printed circuit board 20 with a double-sided wiring configuration, it is possible to discharge ESD via the conductive portion 24 that is on the rear surface side of the connection surface 27 and isolated from the conductor layer 22 by the base member 21 that is excellent in the insulation property. Thereby, it is possible to cause ESD to flow a bypass via the conductive portion 24 of the flexible printed circuit board 20 and to be discharged without affecting an electronic component, which is connected to and mounted on the conductor layer 22 of the flexible printed circuit board 20, as well.

Further, as described above, a configuration in which ESD is discharged to the ground via the flexible printed circuit board 20 that is mounted on the display panel 10 is provided. Thereby, also in the display module 1 in which a bezel made of metal is not provided and to which a touch panel is directly stuck, it is possible to achieve an effect with respect to ESD that comes into the display panel 10 from a periphery of the touch panel.

As illustrated in FIGS. 2 and 3, the exposed portion 28 of the flexible printed circuit board 20 is formed in a range over a length L of the conductive portion 24 of flexible print. Moreover, the exposed portion 28 of the flexible printed circuit board 20 is formed so that an exposed width w1 is wider than a connection width w2 of the connection surface 27.

With such a configuration, a step is not generated by the exposed portion 28 in a process of press-bonding the flexible printed circuit board 20 to the display panel 10 with use of the anisotropic conductive film. Thus, even when the exposed portion 28 is provided on the rear surface side of the connection surface 27 of the flexible printed circuit board 20, it is possible to connect the flexible printed circuit board 20 to the display panel 10.

### Embodiment 2

Embodiment 2 of the invention will be described as follows with reference to FIG. 5. Note that, for convenience of description, a member having the same function as that of the member described in the above-described embodiment will be given the same reference sign, and description thereof will be omitted. Moreover, since a configuration of the display module 1, which has been described with reference to FIG. 1, is similar to that of Embodiment 1, description thereof will be omitted.

In Embodiment 1 described above, a configuration in which the exposed portion 28 of the flexible printed circuit board 20 is formed so that the exposed width w1 is wider than the connection width w2 of the connection surface 27 is provided.

In Embodiment 2, an exposed portion 128 is formed to be considerably smaller than the connection surface 27. On the side of the rear surface of the base member 21, the conductive portion 24 is provided. An opening 129 in which the conductive portion 24 is exposed is provided in the film coverlay 25 that covers the conductive portion 24. As illustrated in FIG. 5, the exposed portion 128 is provided by exposing the conductive portion 24 via the opening 129 that is formed in the film coverlay 25. Note that, a size of a diameter of the opening 129 is able to be about 0.1 mm to 2 mm.

In the film coverlay 25, a plurality of openings 129 are formed. In this manner, by exposing the conductive portion 24 via the plurality of respective openings 129, a plurality of exposed portions 128 are provided in the flexible printed circuit board 20. The plurality of exposed portions 128 may be provided side by side on a line in a direction of the length L of the conductive portion 24 of the flexible printed circuit board 20.

With such configurations, it is possible to cause ESD that is generated outside the display module 1 to flow to the conductive portion 24 of the flexible printed circuit board 20 from the exposed portion 128 and to be discharged from the ground via the flexible printed circuit board 20.

Moreover, the exposed portion 128 is configured to be exposed to an outside via the opening 129 that is formed in the film coverlay 25 and formed so as to have a size considerably smaller than that of the connection surface 27. Thereby, a step is not generated by the exposed portion 28, which is provided on the rear surface side of the connection surface 27, in the process of press-bonding the flexible printed circuit board 20 to the display panel 10 with use of the anisotropic conductive film. Thus, it is possible to reduce influence at a time when the flexible printed circuit board 20 is mounted on the display panel 10, which is generated because the exposed portion 128 is provided.

### Embodiment 3

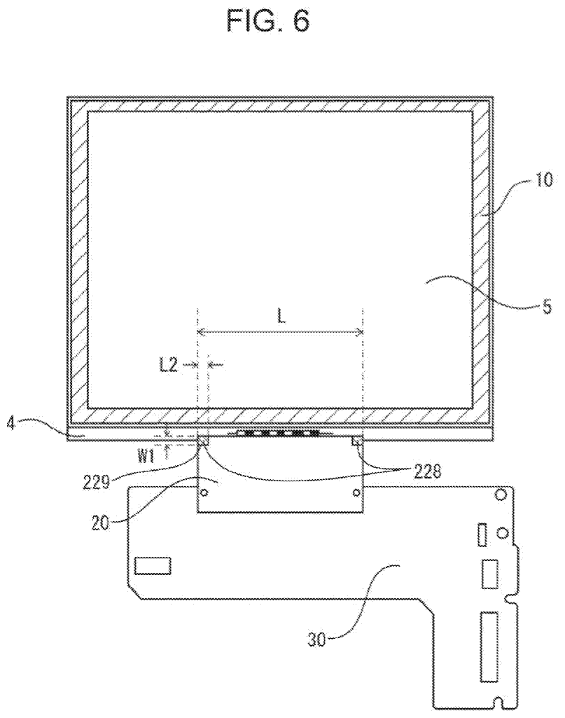

Embodiment 3 of the invention will be described as follows with reference to FIG. 6. Note that, for convenience of description, a member having the same function as that of the member described in the above-described embodiments will be given the same reference sign, and description thereof will be omitted. Moreover, since the configuration of the display module 1, which has been described with reference to FIG. 1, is similar to that of Embodiment 1, description thereof will be omitted.

In Embodiment 2 described above, in order to reduce influence at the time when the flexible printed circuit board 20 is mounted on the display panel 10, a configuration in which the exposed portions 128 are provided in the flexible printed circuit board 20 by forming the plurality of openings 29, each of which is like a pinhole, in the film coverlay 25 is provided.

In Embodiment 3 here, another example in which an exposed portion 228 is provided in the flexible printed circuit board 20 while the influence at the time when the flexible printed circuit board 20 is mounted on the display panel 10 is suppressed to be small will be described.

As illustrated in FIG. 6, in the film coverlay 25 that covers the conductive portion 24, an opening 229 is formed in each of both end parts in the direction of the length L, which are at an edge part of the display panel 10. In the flexible printed circuit board 20, the exposed portion 228 in which the conductive portion 24 is exposed via the opening 229 is provided. It is desired that the opening 229 is formed so that a length L2 is from an end of an external shape of the conductive portion 24 to an outermost terminal and a width W1 is a width of about a half of a width W2 of the connection surface 27.

With such configurations, it is possible to cause ESD that is generated outside the display module 1 to flow to the conductive portion 24 of the flexible printed circuit board 20 from the exposed portion 228 and to be discharged from the ground via the flexible printed circuit board 20.

In addition, each of the both end parts of the flexible printed circuit board 20, which are at the edge part of the display panel 10, is a part in which a terminal, such as a dummy terminal, which does not affect a function is able to be provided. The exposed portion 228 is formed in the part which does not affect a function of the flexible printed circuit board 20. Therefore, even in a case where, at a time of press-bonding the flexible printed circuit board 20 to the display panel 10 with use of the anisotropic conductive film, press-bonding is insufficient at a part in which the opening 229 is provided, the exposed portion 228 does not affect the function of the flexible printed circuit board 20. Thus, without affecting the function of the flexible printed circuit board 20, it is possible to form a bypass route of ESD by providing the flexible printed circuit board 20 with a double-sided wiring configuration and providing the exposed portion 228 on the rear surface side of the connection surface 27.

### CONCLUSION

A display module 1 according to an aspect 1 of the invention has a configuration in which, in the display module 1 including: a display panel 10; a flexible printed circuit board 20 that is connected to the display panel 10; and a circuit board 30 that supplies a drive signal to the display panel 10 via the flexible printed circuit board 20, the flexible printed circuit board 20 includes an exposed portion 28, in which a conductive portion 24 connected to a ground is exposed, on a rear surface side of a connection surface 27 to the display panel 10.

With the aforementioned configuration, it is possible to cause ESD to flow to the conductive portion 24 from the exposed portion 28 that is provided on the rear surface side of the connection surface 27 of the flexible printed circuit board 20 and to be discharged to the ground. Thereby, by using the flexible printed circuit board 20 as a bypass route of the ESD, it is possible to prevent the ESD from flowing into the COG 11 or the display panel. Thus, the display module 1 improvement in ESD resistance of which is achieved is able to be provided.

The display module 1 according to an aspect 2 of the invention may have a configuration in which, in the aforementioned aspect 1, the conductive portion 24 is electrically connected to a ground of a case through the circuit board 30.

With the aforementioned configuration, it is possible to cause ESD, which is caused to flow a bypass via the flexible printed circuit board 20, to be discharged to the ground of the case via the circuit board 30.

The display module 1 according to an aspect 3 of the invention may have a configuration in which, in the aforementioned aspect 1 or 2, the exposed portion 28 is formed to be wider than the connection surface 27 by which the flexible printed circuit board 20 is connected to the display panel 10.

With the aforementioned configuration, in a process of press-bonding the flexible printed circuit board 20 to the display panel 10 with use of an anisotropic conductive film, a step is not generated between the exposed portion 28 that serves as a surface part to which a load is applied and the connection surface 27 that is connected to the display panel 10. Thus, it is possible to mount the flexible printed circuit board 20 on the display panel 10 without being subject to influence caused by providing the exposed portion 28.

The display module 1 according to an aspect 4 of the invention may have a configuration in which, in the aforementioned aspect 1 or 2, the conductive portion 24 is exposed in exposed portions 128 via a plurality of openings 129 that are formed in a film coverlay (cover layer) 25 which covers the conductive portion 24.

With the aforementioned configuration, by setting a size of each of the openings 129 to be considerably smaller than that of the connection surface 27, it is possible to suppress influence at a time when the flexible printed circuit board 20 is mounted on the display panel 10 to be small.

The display module 1 according to an aspect 5 of the invention may have a configuration in which, in the aforementioned aspect 1 or 2, an exposed portion 228 is formed in an end part of the rear surface side of the connection surface 27 by which the flexible printed circuit board 20 is connected to the display panel 10.

With the aforementioned configuration, the exposed portion 228 is formed in a corner of the rear surface side of the connection surface 27, which does not affect a function of the flexible printed circuit board 20. Thus, even in a case where the exposed portion 228 is provided and therefore press-bonding of the connection surface 27 with respect to the display panel 10 is insufficient at a position corresponding to the exposed portion 228, it is possible to prevent the function of the flexible printed circuit board 20 from being affected.

The invention is not limited to each of the embodiments described above, and may be modified in various manners within the scope indicated in the claims and an embodiment achieved by appropriately combining technical means disclosed in each of different embodiments is also encompassed in the technical scope of the invention. Further, by combining the technical means disclosed in each of the embodiments, a new technical feature may be formed.

### REFERENCE SIGNS LIST

1 display module
4 terminal region
10 display panel
11 COG
15 bezel
16 plastic frame
17 backlight
18 backlight case
19 rear cover
20 flexible printed circuit board
21 base member
22 conductor layer
23, 25 film coverlay
24 conductive portion
27 connection surface
28, 128, 228 exposed portion
29, 129, 229 opening
30 circuit board

1. A display module comprising: a display panel; a flexible printed circuit board that is connected to the display panel; and a circuit board that supplies a drive signal to the display panel via the flexible printed circuit board, wherein
the flexible printed circuit board includes an exposed portion, in which a conductive portion connected to a ground is exposed, on a rear surface side of a connection surface to the display panel.

2. The display module according to claim 1, wherein the conductive portion is electrically connected to a ground of a case through the circuit board.

3. The display module according to claim 1, wherein the exposed portion is formed to be wider than the connection surface by which the flexible printed circuit board is connected to the display panel.

4. The display module according to claim 1, wherein the conductive portion is exposed in the exposed portion via a plurality of openings that are formed in a cover layer which covers the conductive portion.

5. The display module according to claim 1, wherein the exposed portion is formed in an end part of the rear surface side of the connection surface by which the flexible printed circuit board is connected to the display panel.
